(19) United States
(12) Patent Application Publication
(10) Pub. No.: US 2007/0145422 A1
(43) Pub. Date: Jun. 28, 2007

(54) CMOS Image Sensor and Manufacturing Method Thereof

(76) Inventor: Dong Bin Park, Daejeon (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/611,282

(22) Filed: Dec. 15, 2006

(30) Foreign Application Priority Data
Dec. 28, 2005 (KR) 10-2005-0132638

(51) Int. Cl. H01L 27/148

(52) U.S. Cl. 257/233

(57) ABSTRACT

A CMOS image sensor and method of manufacturing same is provided. The CMOS image sensor can include: photodiodes formed on a semiconductor substrate for generating a charge according to an amount of incident light; a first planarization layer formed on the semiconductor substrate; a plurality of color filter layers formed on the first planarization layer, an upper surface of each of the color filter layers being curved; and a plurality of microlenses formed on the plurality of color filter layers.

### RELATED APPLICATION(S)

This application claims priority under 35 U.S.C. §119(e) of Korean Patent Application No. 10-2005-0132638 filed Dec. 28, 2005, which is incorporated herein by reference in its entirety.

### FIELD OF THE INVENTION

The present invention relates to an image sensor and a manufacturing method thereof.

### BACKGROUND OF THE INVENTION

In general, image sensors are semiconductor devices that transform an optical image to electrical signals. Image sensors are generally classified as charge coupled device (CCD) image sensors or complementary metal oxide semiconductor (CMOS) image sensors.

The CMOS image sensor includes a photodiode for sensing irradiated light and a CMOS logic circuit for generating data by processing the detected light into electric signals. As the amount of light received in the photodiode increases, the photosensitivity of the image sensor improves.

In order to increase the photosensitivity of an image sensor, one method is to increase a fill factor of the area of the photodiode to the total area of the image sensor. Another method is to change a path of light incident to a region except for the photodiode to focus it to the photodiode.

A typical example of the light focusing technology is to form a microlens. The microlens is formed in a convex shape and is made with materials of excellent optical transmittance at an upper portion of the photodiode. It refracts a path of incident light, thereby irradiating more light to the photodiode region.

In this case, the microlens refracts light horizontal to an optical axis of the microlens in order to form a focus thereof at a predetermined position on the optical axis.

Hereinafter, a CMOS image sensor according to the related art will be explained with reference the accompanying drawings.

FIG. 1 is a cross-sectional view showing a CMOS image sensor according to the related art.

Referring to FIG. 1, the CMOS image sensor includes at least one photodiode 12, a first planarization layer 13, red (R), green (G), and blue (B) color filter layers 14, a second planarization layer 15, and a microlens 16. The photodiode 12 is formed in a surface of a semiconductor substrate 11 and generates a charge according to an amount of incident light. The first planarization layer 13 is formed at an entire surface of the semiconductor substrate 11 including the photodiode 12. The R, G, and B color filter layers 14 are formed on the first planarization layer 13 and pass lights of specific wavelengths. The second planarization layer 15 is formed on the color filter layers 14. The microlens 16 is formed on the second planarization layer 15 in a convex shape having a predetermined curvature. The microlens 16 causes light to transmit a corresponding color filter layer 14, and focuses the light towards the photodiode 12.

A curvature and a height of the microlens 16 are determined according to the focused light. The microlens 16 is made of a polymer-based resin through a patterning process incorporating deposition, exposure, and development, and a reflow process.

The optimal size, thickness, and curvature radius for a microlens 16 is determined by the size, position, and shape of a unit pixel; the thickness of a photo sensing device; and the height, position, and size of a light shield layer.

In a method for manufacturing the CMOS image sensor according to the related art, a microlens 16 is formed to increase the focusing performance of light, which is an important factor for controlling the characteristics of an image sensor.

When a natural light is irradiated, the microlens 16 functions to focus more light to the photodiode 12 through color filter layers 14.

The microlens 16 focuses light incident to the image sensor, and light filtered in the color filter layers 14 is incident to the photodiode corresponding to a particular color filter layer 14.

However, the CMOS image sensor according to the related art has the following problems.

That is, the color filter layers 14 are formed having different thicknesses according to the particular wavelength for filtering, thereby resulting in step coverage, or height differences. In order to compensate for the step height differences from the formation of the color filter layers 14, a second planarization layer 15 is formed at an entire surface of the substrate.

The light must pass through the second planarization layer 15 before reaching the color filter layers. The thickness of the second planarization layer can degrade the characteristics of the image sensor. For example, noise can be caused by light being incident on unintended photodiodes.

### BRIEF SUMMARY

Accordingly, embodiments of the present invention are directed to a CMOS image sensor and a method for manufacturing the same that substantially obviates one or more problems due to limitations and/or disadvantages of the related art.

An object of the present invention is to provide a CMOS image sensor capable of enhancing the photosensitivity by minimizing noise components.

A second object of the present invention is to provide a CMOS image sensor capable of improving a condensing performance.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS (complementary metal oxide semiconductor) image sensor comprising: photodiodes formed on a semiconductor substrate for generating a charge according to an amount of incident light; a first planarization layer formed on the photodiodes; a plurality of color filter layers formed on the first planarization layer, wherein an upper side of each of the color filter layers are curved; and a plurality of microlenses formed on the plurality of color filter layers.

In another embodiment of the present invention, there is provided a CMOS (complementary metal oxide semiconductor) image sensor comprising: photodiodes formed on a semiconductor substrate for generating a charge according to an amount of incident light; a first planarization layer formed on the photodiodes, wherein a top surface of the planarization layer has different heights according to a region thereof; a plurality of color filter layers formed on the first planarization layer; and a plurality of microlenses formed on the plurality of color filter layers.

In another aspect of the present invention, there is provided a method for manufacturing a CMOS (complementary metal oxide semiconductor) image sensor comprising: forming a plurality of photodiodes on a semiconductor substrate; forming a first planarization layer on the plurality of photodiodes, the first planarization layer being formed to different heights according to a region thereof; forming a plurality of color filter layers on the first planarization layer; and forming a plurality of microlenses on the plurality of color filter layers.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is a cross-sectional view showing a CMOS image sensor according to the related art.

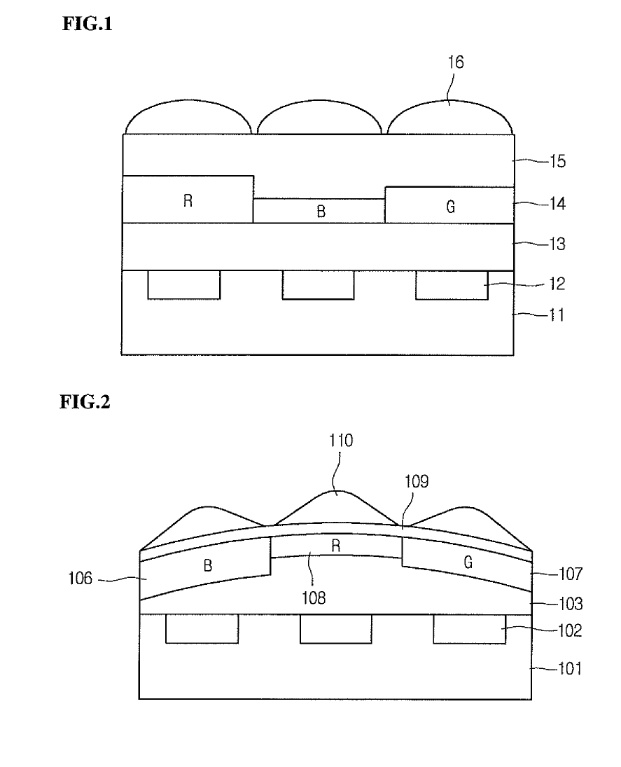

FIG. 2 is a cross-sectional view showing a CMOS image sensor according to an embodiment of the present invention.

FIGS. 3A through 3G are cross-sectional views for describing a method for manufacturing a CMOS image sensor according to an embodiment of the present invention.

FIG. 4 is a cross-sectional view showing a CMOS image sensor according to another embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor and a method for manufacturing the same according to an embodiment of present invention will be described with reference to the accompanying drawings.

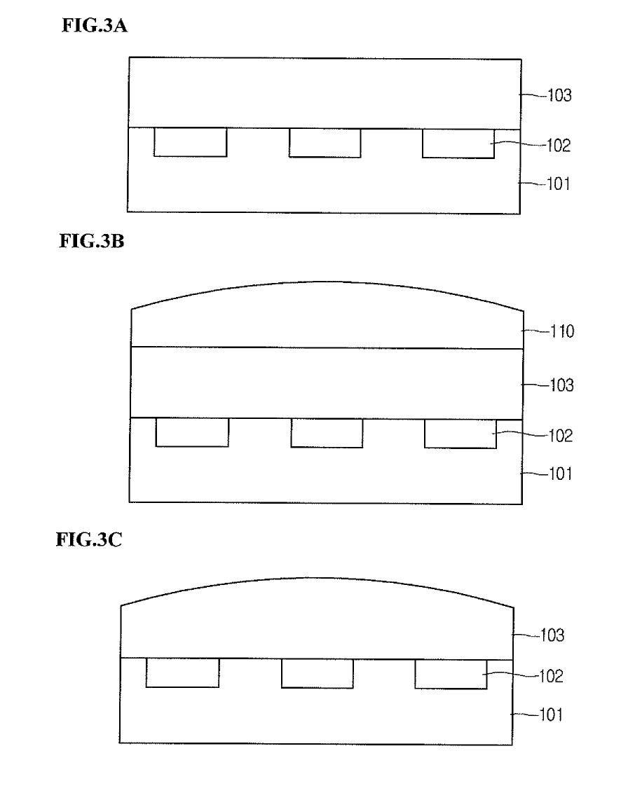

FIG. 2 is a cross-sectional view showing a CMOS image sensor according to an embodiment of the present invention.

Referring to FIG. 2, the CMOS image sensor can include at least one photodiode 102, a first planarization layer 103, a blue (B) color filter layer 106, a green (G) color filter layer 107, a red (R) color filter layer 108, a second planarization layer 109, and microlenses 110. The at least one photodiode 102 can be formed on a semiconductor substrate 101, and generates a charge according to an amount of incident light. The first planarization layer 103 can be formed on the semiconductor substrate 101 including the photodiode 102 in a convex shape. The blue (B) color filter layer 106 can be formed in a first trench having a predetermined depth in the first planarization layer 103 having the convex shape. The green (G) color filter layer 107 can be formed in a second trench formed in the first planarization layer 103 to a depth less than that of the first trench. In one embodiment, the second trench can be spaced apart from the first trench. The red (R) color filter layer 108 can be formed on the first planarization layer 103 between the blue color filter layer 106 and the green color filter layer 108. The second planarization layer 109 can be formed on the blue, green, and red color filer layers 106, 107, and 108. The microlenses 110 can be formed on the second planarization layer 109 corresponding to the color filer layers 106, 107, and 108.

Here, the blue, green, and red color filer layers 106, 107, and 108 can be formed in a convex shape by the first and second trenches, and the top surfaces can provide a gentle curve on the whole. In one embodiment, because boundaries of the upper sides of adjacent color filter layers do not have a height difference, the second planarization layer 109 can be thinly formed.

In particular, the second planarization layer 109 can be formed having the same curvature as that of the upper sides of the color filter layers 106, 107, and 108, and can be thinly formed with a uniform thickness.

In another embodiment, because boundaries of the upper sides of adjacent color filter layers do not have a height difference, and the upper sides thereof are formed in a curved shape, the second planarization layer 109 can be selectively formed. That is, it is possible to form the microlenses 10 directly at the upper sides of the color filter layers 106, 107, and 108 without forming the second planarization layer 109.

Since the microlenses 110 can be formed on the second planarization layer 109 in a curved shape, the subject image sensor can have a greater condensing area in comparison with an image sensor having a planarization layer formed in a plane.

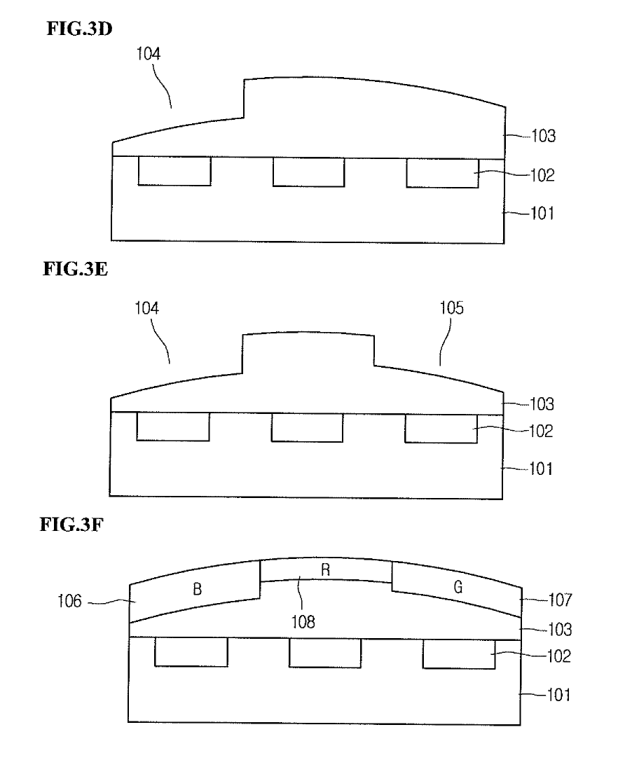

FIGS. 3A through 3G are cross-sectional views for describing a method for manufacturing a CMOS image sensor according to an embodiment of the present invention.

Referring to FIG. 3A, at least one photodiode 102 for generating a charge according to an amount of incident light can be formed on the semiconductor substrate 101. Then, an interlayer dielectric (not shown) and a first planarization layer 103 can be formed on the photodiode 102.

Here, the interlayer dielectric (not shown) can be formed as a multi-layer. Specifically, after one interlayer dielectric has been formed, a light shield layer for blocking light from being incident to a region not having a photodiode 102 can be formed, and another interlayer dielectric can be formed thereon.

In one embodiment the interlayer dielectric can be made of an oxide such as undoped silicate glass (USG).

The first planarization layer 103 can be formed of a SiN layer.

Referring to FIG. 3B, a photoresist layer can be coated on the first planarization layer 103, and patterned to remain only at a pixel array region by exposure and developing processes. Next, the patterned photoresist layer can be reflown at a temperature ranging from 150 to 200° C. to form a convex surface, thereby forming the photoresist layer 110.

Referring to FIG. 3C, a blank etching process can be performed with respect to the photoresist layer 110 having the convex shape and the first planarization layer 103. The etching process uses an etch selectivity of 1:1 to form a convex surface for the first planarization layer 103.

Accordingly, the thickness of the first planarization layer 103 becomes thinner as it goes from its central portion toward its edge portion.

Referring to FIG. 3D, a predetermined part of the first planarization layer 103 having the convex shape can be selectively removed by photolithography and etching processes to form a first trench 104 having a predetermined depth from the surface. Here, the first trench 104 is a first region, which will be a formation region of a blue color filter layer.

Referring to FIG. 3E, a second predetermined part of the first planarization layer 103, which is spaced apart from the first trench 104, can be selectively removed through photolithography and etching processes to form a second trench 105 having a depth less than that of the first trench 104. Here, the second trench 105 is a second region, which will be a formation region of a green color filter layer.

Referring to FIG. 3F, the entire surface of the semiconductor substrate including the first and second trenches 104 and 105 can be coated with a resist for a blue color filter, and then the resist can be exposed and developed to form a blue color filter layer 106 inside the first trench 104. In a specific embodiment the reticle used when forming the first trench 104 can be used as a reticle for forming the blue color filter layer 106.

Next, a resist for a green filter can be coated on the substrate, and exposed and developed to form a green color filter layer 107 in the second trench 105. In a specific embodiment, the reticle used when forming the second trench 105 can be used as a reticle for forming the green color filter layer 107.

Then, a resist for a red filter can be coated on the substrate, and exposed and developed to form a red color filter layer 108 on the first planarization layer 103 between the blue color filter layer 106 and the green color filter layer 107.

Although the above described embodiment of the present invention indicates that the color filter layers are formed in the order of the blue color filter 106, green color filter layer 107, and then red color filter layer 108, the present invention is not limited thereto. The order of formation for the color filter layers can be optionally adjusted.

Referring to FIG. 3G, a second planarization layer 109 for a focus distance adjustment and a flatness security for forming a lens layer can be formed on an entire surface of the semiconductor substrate 101 including the color filter layers 106, 107, and 108.

Accordingly, in order to reduce the thickness of the second planarization layer 109 so that natural light passing through the microlens may directly enter a color filter layer, the boundaries of adjacent color filter layers do not have a height difference, and upper sides of the color filter layers 106, 107, and 108 have a curved shape.

That is, in embodiments of the present invention, prior to a formation of the color filter layers 106, 107, and 108, a trench is formed in the first planarization layer 103 for respective color filter layers.

In addition, since the first planarization layer 103 has a convex surface, the color filer layers 106, 107, and 108 and the second planarization layer 209 also have a convex curved surface.

Referring again to FIG. 3G, a material layer for forming a microlens can be coated on the second planarization layer 109 having the convex shape, and can be patterned using exposure and developing processes to form a microlens pattern.

Here, a resist or TEOS can be used as the material layer for forming the microlens.

Then, the microlens pattern can be reflown at a temperature ranging from 150 to 300° C. to form a microlens 110.

Here, the reflow process may use a hot plate or a furnace. During the contraction heating method, the curvature of the microlens 110 changes. The focusing efficiency of the microlens changes according to the curvature of the microlens 110,

Subsequently, an infrared ray is irradiated to the microlens 110 to cure the material. Here, by irradiating and curing the microlens 110, the microlens 110 can maintain an optimal curvature radius.

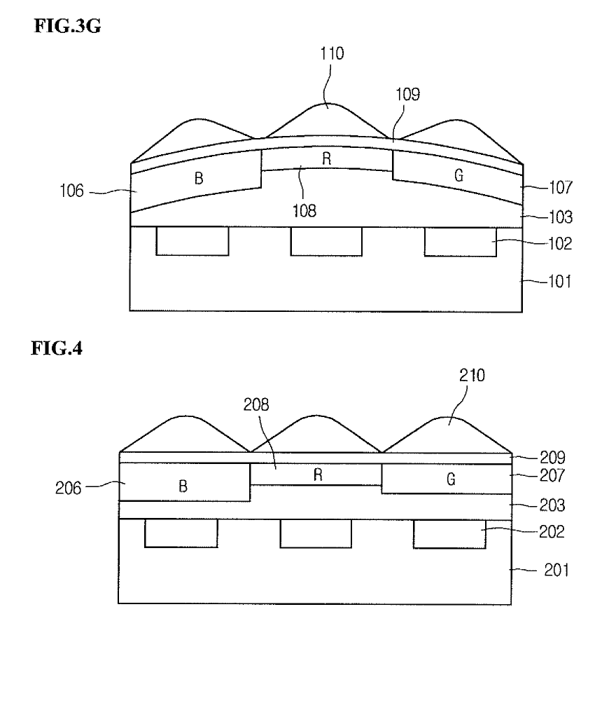

FIG. 4 is a cross-sectional view showing a CMOS image sensor according to another embodiment of the present invention.

Referring to FIG. 4, the CMOS image sensor can include at least one photodiode 202, a first planarization layer 203, a blue (B) color filter layer 206, a green (G) color filter layer 207, a red (R) color filter layer 208, a second planarization layer 209, and microlenses 210. The at least one photodiode 202 can be formed on a semiconductor substrate 201 for generating a charge according to an amount of incident light. The first planarization layer 203 can be formed on the semiconductor substrate 101 including the photodiode 102, and has different heights according to a region thereof. The blue (B) color filter layer 206 can be formed in a first trench, which is formed in the first planarization layer 203 to a predetermined depth. The green (G) color filter layer 207 can be formed in a second trench formed in the first planarization layer 203 to a depth less than that of the first trench. Here, the second trench can be spaced apart from the first trench. The red (R) color filter layer 208 can be formed on the first planarization layer 203 between the blue color filter layer 206 and the green color filter layer 207. The second planarization layer 209 can be formed on the blue, green, and red color filer layers 206, 207, and 208. The microlenses 210 can be formed on the second planarization layer 209 corresponding to the color filer layers 206, 207, and 208.

Here, upper surfaces of the blue color filter layer 206, the green color filter layer 207, and the red color filter layer 208 can be formed to have the same height by the forming of the first and second trenches.

Namely, because there is no height difference between the color filter layers 206, 207, and 208, the second planarization layer 209 can be thinly formed. Further, it is possible to directly form the microlens 210 on the color filter layers without a formation of the second planarization layer 209.

The following is a method for manufacturing a CMOS image sensor according to another embodiment of the present invention.

First, at least one photodiode 202 for generating a charge according to an amount of incident light can be formed on the semiconductor substrate 201, and an interlayer dielectric (not shown) and a first planarization layer 203 can be formed thereupon. In an embodiment, the first planarization layer 203 can be formed of SiN.

Then, a predetermined part of the first planarization layer 203 can be selectively removed using photolithography and etching processes to form a surface having different heights according to a region thereof. In particular, the different heights can be a result of trenches formed to different depths in regions of the first planarization layer.

The blue color filter layer 206, the green color filter layer 207, and the red color filter layer 208 can be formed at the regions having different heights on the first planarization layer 203. The blue color filter layer 206, the green color filter layer 207, and the red color filter layer 208 can be formed to have different thicknesses. However, because of the different height regions of the first planarization layer, upper sides of the blue color filter layer 206, the green color filter layer 207, and the red color filter layer 208 may be formed to the same height.

A second planarization layer 209 for a focus distance adjustment and flatness security for forming a lens layer can be formed on an entire surface of the semiconductor substrate 201 including the color filter layers 206, 207, and 208.

Next, a material layer for forming a microlens can be coated on the second planarization layer 209, and patterned using exposure and developing processes to form a microlens pattern. Here, a resist or TEOS can be used as the material layer for forming the microlens.

Then, the microlens pattern can be reflown at a temperature ranging from 150 to 300° C. to form a microlens 210. Here, the reflow process may use a hot plate or a furnace. At this time, according to the contraction heating method, the curvature of the microlens 210 changes. The focusing efficiency of the microlens can be changed according to the curvature of the microlens 210.

Subsequently, an infrared ray can be irradiated to the microlens 210 to cure the material. Here, by irradiating and curing the microlens 210, the microlens 210 can maintain an optimal curvature radius.

As is evident from the above explanation, the CMOS image sensor and a method for manufacturing the same have following effects.

First, respective color filter layers can be formed in a trench in a surface of a first planarization layer to reduce a thickness of the second planarization layer. Thus, natural light passing through the microlens directly enters in a color filter layer in order to enhance the photosensitivity of an image sensor.

Second, because a first planarization layer may be formed to have a convex curved surface and a second planarization layer formed thereon is also formed in a convex shape, a surface area of a microlens is increased to improve a focusing performance of the microlens.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide semiconductor) image sensor comprising:
photodiodes formed on a semiconductor substrate;
a first planarization layer formed on the semiconductor substrate including the photodiodes;
a plurality of color filter layers formed on the first planarization layer, an upper surface of each of the plurality of color filter layers being curved; and
a plurality of microlenses formed on the plurality of color filter layers.

2. The CMOS image sensor according to claim 1, further comprising a second planarization layer formed between the plurality of color filter layers and the plurality of microlenses.

3. A CMOS (complementary metal oxide semiconductor) image sensor comprising:
photodiodes formed on a semiconductor substrate;
a first planarization layer formed on the semiconductor substrate including the photodiodes, wherein the first planarization layer has different heights according to regions thereof;
a plurality of color filter layers formed on the first planarization layer; and
a plurality of microlenses formed on the plurality of color filter layers.

4. The CMOS image sensor according to claim 3, wherein the different heights of the first planarization layer correspond to regions for forming color filter layers of different thicknesses, wherein a smaller height of the first planarization layer corresponds to a region for a thicker color filter layer.

5. The CMOS image sensor according to claim 3, wherein each upper surface of the regions of different heights of the first planarization layer is curved.

6. The CMOS image sensor according to claim 3, further comprising a second planarization layer formed between the plurality of color filter layers and the plurality of microlenses.

7. The CMOS image sensor according to claim 6, wherein the second planarization layer is formed having a uniform thickness.

8. The CMOS image sensor according to claim 3, wherein the plurality of color filter layers form a convex upper surface.

9. The CMOS image sensor according to claim 3, wherein each of the plurality of color filter layers have a top surface formed at the same height.

10. A method for manufacturing a CMOS (complementary metal oxide semiconductor) image sensor, comprising:
forming a plurality of photodiodes on a semiconductor substrate;
forming a first planarization layer on the semiconductor substrate, wherein the first planarization layer is formed to have different heights according to regions thereof;
forming a plurality of color filter layers on the first planarization layer; and
forming a plurality of microlenses on the plurality of color filter layers.

11. The method according to claim 10, wherein forming the first planarization layer on the semiconductor substrate comprises:
forming a first planarization layer of a uniform thickness, and
selectively etching the first planarization layer to have different heights according to regions thereof.

12. The method according to claim 10, wherein forming the first planarization layer on the semiconductor substrate comprises:
forming a first planarization layer of a convex shape, and
selectively etching the convex shaped first planarization layer to have different heights according to regions thereof, wherein upper surfaces of the regions having different heights are curved.

13. The method according to claim 10, further comprising forming a second planarization layer between the plurality of color filter layers and the plurality of microlenses.

14. The method according to claim 13, wherein the second planarization layer is formed having a uniform thickness.

15. The method according to claim 10, wherein upper surfaces of the plurality of color filter layers are formed at the same height.
